(19) United States
(12) Patent Application Publication
(10) Pub. No.: US 2010/0181628 A1
(43) Pub. Date: Jul. 22, 2010

(54) SEMICONDUCTOR DEVICE

(75) Inventors: Kenya Kawano, Hitachinaka (JP); Kisho Ashida, Hitachinaka (JP); Kuniharu Muto, Maebashi (JP); Ichio Shimizu, Tamamura (JP); Tomibumi Inoue, Tokyo (JP)

Correspondence Address: BRUNDIDGE & STANGER, P.C., 2318 MILL ROAD, SUITE 1020, ALEXANDRIA, VA, 22314, US

(73) Assignee: Renesas Technology Corp., Tokyo (JP)

(21) Appl. No.: 12/691,168

(22) Filed: Jan. 21, 2010

(30) Foreign Application Priority Data
Jan. 22, 2009 (JP) 2009-011938

(51) Int. Cl. H01L 23/495; H01L 23/48

(52) U.S. Cl. 257/401; 257/675; 257/692; 257/E23.01; 257/E23.031; 257/E23.051

(57) ABSTRACT

Prevention of disconnection of a bonding wire resulting from adhesive interface delamination between a resin and a leadframe, and improvement of joint strength of the resin and the leadframe are achieved in a device manufactured by a low-cost and simple processing. A boss is provided on a source lead by a stamping processing, and a support pillar is provided in a concave portion on a rear side of the source lead in order to prevent ultrasonic damping upon joining the bonding wire onto the boss, so that an insufficiency of the joint strength between the bonding wire and the source lead is prevented. Also, a continuous bump is provided on the boss so as to surround a joint portion between the source lead and the bonding wire, so that disconnection of the bonding wire resulting from delamination between the resin and the source lead is prevented.

### CROSS-REFERENCE TO RELATED APPLICATION

The present application claims priority from Japanese Patent Application No. JP 2009-011938 filed on Jan. 22, 2009, the content of which is hereby incorporated by reference into this application.

### TECHNICAL FIELD OF THE INVENTION

The present invention relates to a semiconductor device. More particularly, the present invention relates to a technique effectively applied to a semiconductor device in which an element such as a power MOSFET (metal oxide semiconductor field effect transistor), an IGBT (insulated gate bipolar transistor), or a bipolar power transistor is resin-molded (plastic-molded; sealed).

### BACKGROUND OF THE INVENTION

A low-power driving power transistor is known as a transistor for a power supply used in a battery charger (power charger) for a cell-phone, a video camera (video camcorder) etc., a power circuit (source circuit) for office automation (OA) equipment etc., and electrical component equipment for vehicles etc.

In recent years, there has been a tendency of higher power driving regarding such a power semiconductor device. To secure the radiation performance of the semiconductor chip, a semiconductor device in which a die pad (frame) mounting a semiconductor chip is partially exposed has been suggested (for example, Japanese Patent Application Laid-Open Publication No. H07-193173 (Patent Document 1)).

The semiconductor device has a shape as illustrated in FIG. 1. FIG. 1 is a side view illustrating an internal structure of a conventional general semiconductor device 9. The semiconductor device 9 is mounted (assembled) on a top surface of a substrate 8 by a solder reflow process, and an outline of a resin 6 is illustrated by a two-dot chain line in FIG. 1. In FIG. 1, a semiconductor chip 2 is mounted on a leadframe 1, and a boss 7a is provided on the leadframe 1. Electrode terminals (pad) (not illustrated) of the semiconductor chip 2 are joined to the boss 7a by a bonding wire 4 on one side and to a lead terminal 5 by a bonding wire 3 on the other side. They are resin-molded by the resin 6 exposing a part of a rear surface of the leadframe 1 which mounts the semiconductor chip 2, so that the semiconductor device 9 is configured.

In the semiconductor device 9, delamination of an adhesive interface resulting from a difference in thermal expansion coefficient between the resin 6 and the leadframe 1 due to thermal load in a solder reflow process is prevented by providing the boss 7a, so that disconnection and/or delamination of the bonding wire 4 caused by the delamination of the adhesive interface are prevented.

### SUMMARY OF THE INVENTION

It is difficult in practice to form the boss 7a in the semiconductor device 9 of the above-described Patent Document 1 on the leadframe 1. For example, while it is considered that the boss 7a is formed on the leadframe 1 by a cutting processing or the boss 7a as a different component is joined to the leadframe 1 by, for example, a solder process or others, the formation of the boss 7a has a disadvantage in the manufacture cost and mass production of the leadframe 1.

Also, while it is considered that a boss is formed from the rear surface side of the leadframe, for example, by a stamping processing (half stamping or dowel) to perform wire-bonding, the formation of the boss by a stamping processing only causes a space to be formed in a concave portion on a rear surface side of the boss. Therefore, there is a possibility that ultrasonic energy is damped upon bonding-wire joint, and the joint strength between the bonding wire and the leadframe cannot be sufficiently obtained.

Therefore, by the adhesive interface delamination resulting from a difference in thermal expansion coefficient between the resin and the leadframe due to thermal load in the solder reflow process, excessive stress is applied to a joint portion between the bonding wire and the leadframe, and it is concerned that disconnection and/or delamination of the bonding wire are caused.

A preferred aim of the present invention is, regarding a semiconductor device having a structure in which a bonding wire is joined onto a leadframe, to provide a highly-reliable and low-cost semiconductor device by a simple processing, the semiconductor device in which the joint strength between a bonding wire and a leadframe is improved and disconnection and/or delamination of the bonding wire resulting from adhesive interface delamination between a resin and the leadframe are prevented before they occur.

The above and other preferred aims and novel characteristics of the present invention will be apparent from the description of the present specification and the accompanying drawings.

The typical ones of the inventions disclosed in the present application will be briefly described as follows.

A semiconductor device of the present invention includes: a leadframe having a first lead arranged on a die pad portion and in a vicinity of the die pad portion; a semiconductor chip mounted on the die pad portion; a bonding wire electrically connecting the first lead and an electrode formed on a surface of the semiconductor chip; and a resin molding the semiconductor chip, the leadframe, the first lead, and the bonding wire. And, a boss to be a bonding portion of the bonding wire is provided on a top surface of the first lead at a joint surface between the first lead and the bonding wire, a concave portion is formed on a part of a rear side of the boss, and a support pillar (or simply called as pillar) formed of a part of the first lead is formed by a stamping processing, the support pillar being positioned right below the bonding portion inside the concave portion of the first lead and reaching the same height as that from a rear surface of the boss to a rear surface of the first lead.

The effects obtained by typical aspects of the present invention disclosed in the present application will be briefly described below.

By providing the support pillar in the concave portion on the rear side of the boss formed on the leadframe, ultrasonic damping upon bonding wire joint can be prevented, so that the bonding wire and the leadframe can be strongly jointed.

Also, by providing a continuous boss in a periphery of the joint portion between the leadframe and the bonding wire, it is possible to prevent adhesive interface delamination between the resin and the leadframe due to thermal load in a solder ref low process and disconnection of the bonding wire resulting from the delamination before they occur.

Further, since the boss in the bonding portion is formed by pressing the leadframe, the semiconductor device can be formed by a low-cost and simple processing.

### BRIEF DESCRIPTIONS OF THE DRAWINGS

FIG. 1 is a side view illustrating an internal structure of a conventional semiconductor device;

FIG. 2 is a cross-sectional view taken along the line A-A in FIG. 3;

FIG. 3 is a plan view illustrating an internal structure of a semiconductor device according to a first embodiment of the present invention;

FIG. 4 is a plan view illustrating an appearance of the semiconductor device as viewed from a top surface according to the first embodiment of the present invention;

FIG. 5 is a plan view illustrating an appearance of the semiconductor device as viewed from a bottom surface according to the first embodiment of the present invention;

FIG. 6 is a side view illustrating an appearance of a semiconductor chip embedded in a semiconductor device of the present invention;

FIG. 7 is a cross-sectional view taken along the line B-B in FIG. 8;

FIG. 8 is a plan view illustrating an internal structure of a semiconductor device according to a second embodiment of the present invention;

FIG. 9 is a plan view illustrating an appearance of the semiconductor device a viewed from a top surface according to the second embodiment of the present invention;

FIG. 10 is a plan view illustrating an appearance of the semiconductor device as viewed from a bottom surface according to the second embodiment of the present invention;

FIG. 11 is a cross-sectional view taken along the line C-C in FIG. 12;

FIG. 12 is a plan view illustrating an internal structure of a semiconductor device according to a third embodiment of the present invention;

FIG. 13 is a plan view illustrating an appearance of the semiconductor device as viewed from a top surface according to the third embodiment of the present invention;

FIG. 14 is a plan view illustrating an appearance of the semiconductor device as viewed from a bottom surface according to the third embodiment of the present invention;

FIG. 15 is a cross-sectional view taken along the line E-E in FIG. 16;

FIG. 16 is a plan view illustrating an internal structure of a semiconductor device according to a fourth embodiment of the present invention;

FIG. 17 is a plan view illustrating an appearance of the semiconductor device as viewed from a top surface according to the fourth embodiment of the present invention;

FIG. 18 is a plan view illustrating appearance from a bottom surface of the semiconductor device according to the fourth embodiment of the present invention; and

FIG. 19 is a cross-sectional view illustrating a method of manufacturing the semiconductor device according to the fourth embodiment of the present invention.

### DESCRIPTIONS OF THE PREFERRED EMBODIMENTS

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof.

Also, in the embodiments described below, when referring to the number of elements (including number of pieces, values, amount, range, and the like), the number of the elements is not limited to a specific number unless otherwise stated or except the case where the number is apparently limited to a specific number in principle. The number larger or smaller than the specified number is also applicable.

Further, in the embodiments described below, it goes without saying that the components (including element steps) are not always indispensable unless otherwise stated or except the case where the components are apparently indispensable in principle. Also, when “formed of A” or “formed by A” is used for describing components and so forth in the embodiments etc., it goes without saying that other components are not eliminated unless otherwise specified to be only the components.

Similarly, in the embodiments described below, when the shape of the components, positional relation thereof, and the like are mentioned, the substantially approximate or similar shapes etc. are included unless otherwise stated or except the case where it can be conceived that they are apparently excluded in principle. The same goes for the numerical value and the range mentioned above.

In addition, when materials and others are mentioned, specified one is a main material unless otherwise stated that it is not a main material and it is apparently not so in principle, and subsidiary components, additives, additional components, and others are not eliminated. For example, a silicon member includes not only pure silicon but also a binary or ternary alloy (for example, SiGe) having additive impurities and silicon as main components or others unless otherwise stated.

Moreover, components having the same function are denoted by the same reference symbols throughout the drawings for describing the embodiment, and the repetitive description thereof will be omitted.

Also, in some drawings used in the embodiments, hatching is used even in a plan view so as to make the drawings easy to see.

### First Embodiment

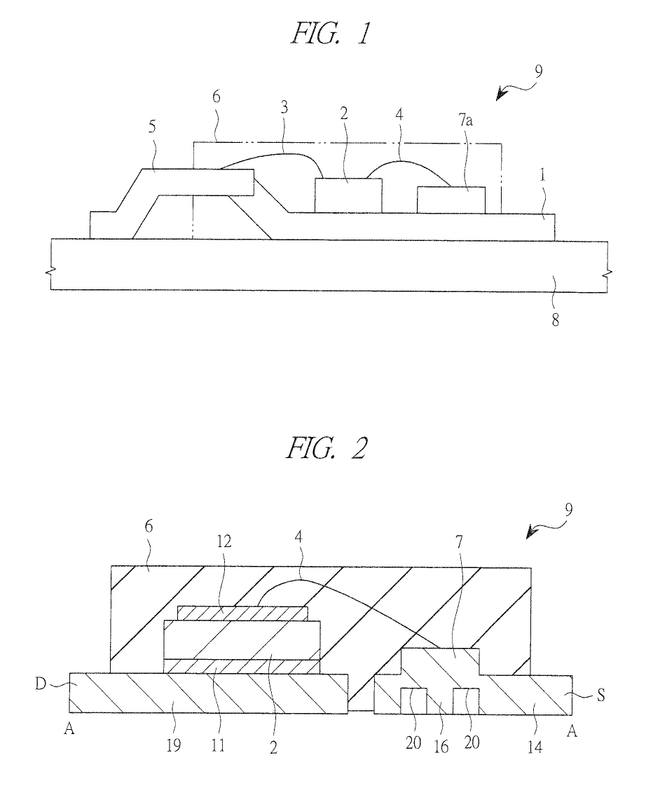

A first embodiment is used for manufacture of a power MOSFET package, and will be described with reference to FIGS. 2 to 6.

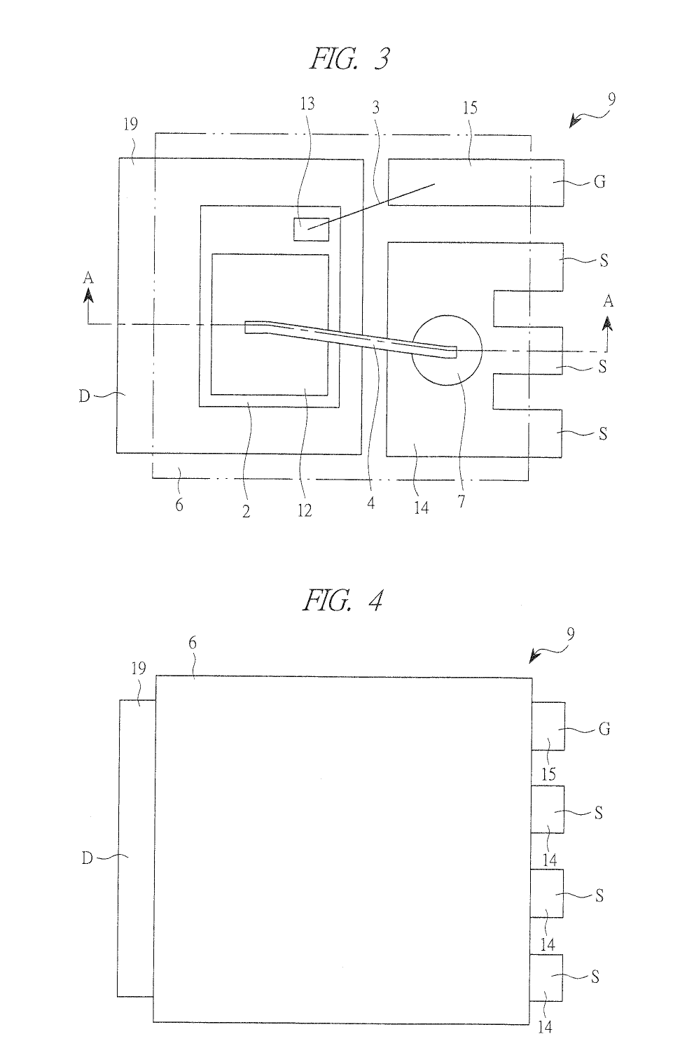

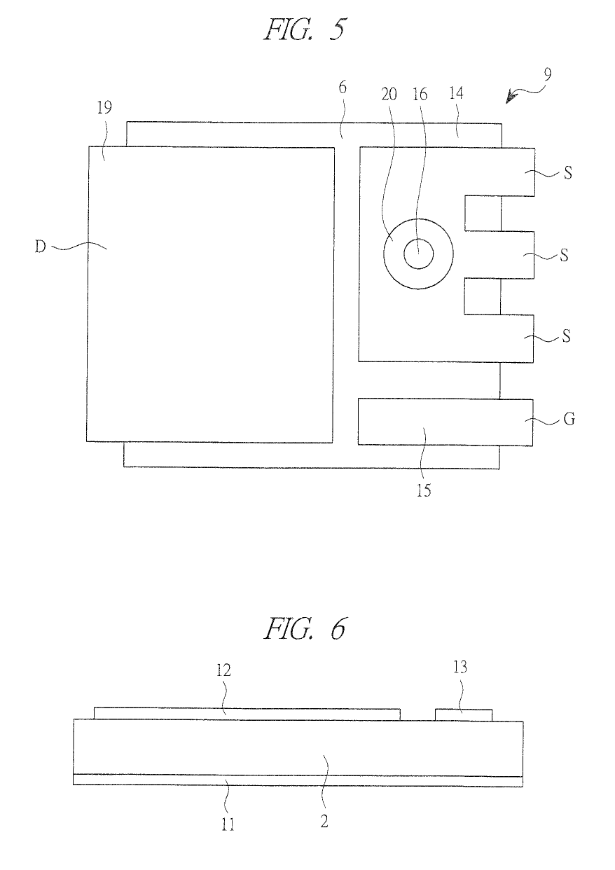

FIG. 2 is a cross-sectional view taken along the line A-A in FIG. 3, and illustrates an internal structure of a semiconductor device 9 according to the present embodiment. FIG. 3 is a plan view illustrating the internal structure of the semiconductor device 9 of FIG. 2, and an outline of a resin 6 is illustrated by a two-dot chain line. Also, FIGS. 4 and 5 illustrate appearance configurations of the semiconductor device 9 according to the present embodiment. FIG. 4 is a top plan view of the semiconductor device 9, and FIG. 5 is a bottom plan view of the same.

The present embodiment is an example of using the present invention for a vertical power transistor. That is, a field effect transistor having a drain electrode “D”, a source electrode “S”, and a gate electrode “G” is embedded in a semiconductor chip 2, and the semiconductor chip 2 is embedded in the semiconductor device 9.

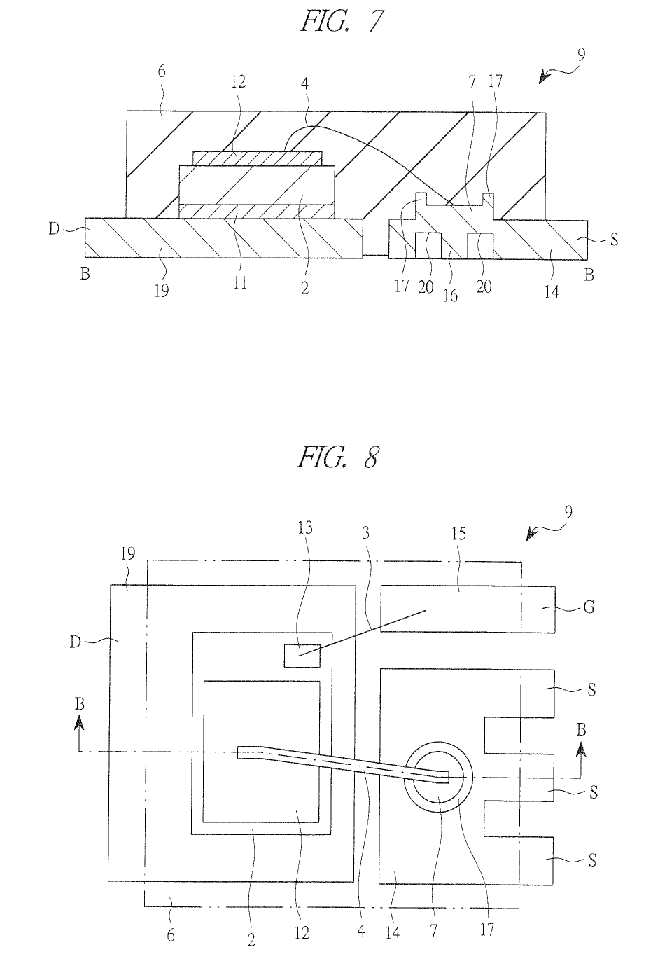

For example, a vertical power MOSFET is formed in the semiconductor chip 2, and the semiconductor chip 2 has a drain electrode 11 on its bottom (rear) surface, and has a source electrode 12 and a gate electrode 13 on its top (main) surface as illustrated in FIG. 6. The semiconductor chip 2 is mounted on a die pad 19 also functioning as a drain lead as illustrated in FIG. 2.

At this time, for example, a solder paste or an electrically conductive paste can be used for a die-attach (not illustrated) attaching the drain electrode 11 on the semiconductor chip 2 to the die pad 19.

The source electrode 12 and the gate electrode 13 are joined to a source lead 14 and a gate lead 15 by bonding wires 4 and 3, respectively. At this time, for example, an Al (aluminum) wire is used for the bonding wire 4 of the source side in which a relatively large current is flown. Note that a material or a cross-sectional area size of the bonding wire 4 may be changed depending on a value of a current flowing in the semiconductor device 9, and for example, an Au (gold) wire, a Cu (copper) wire, or an Al ribbon may be used instead of the Al wire.

On the other hand, for example, an Au wire is used for the bonding wire 3 of the gate side in which a relatively small current is flown. Of course, an Al wire, a Cu wire, or an Al ribbon may be used instead of the Au wire.

They are resin-molded by the resin 6 so as to partially expose the source lead 14, the gate lead 15, and the die pad 19 on which the semiconductor chip 2 is mounted, so that the semiconductor device 9 is configured.

At this time, a boss 7 is provided on the source lead 14 in which a relatively large current is flown. The boss 7 is formed by, for example, a stamping processing, and for example, formed by a half stamping processing from the rear surface side of the source lead 14 with using a pressing machine.

By the anchor effect caused by providing the boss 7, adhesion between the resin 6 and the source lead 14 is improved, so that the delamination between the resin 6 and the source lead 14 due to thermal load in a solder reflow process upon mounting the semiconductor device 9 on a substrate is suppressed.

Here, in a step of forming the boss 7, a support pillar 16 is formed to a concave portion 20 on a rear side of the boss 7. The support pillar 16 prevents ultrasonic damping upon joining the bonding wire 4 and the source lead 14, the ultrasonic damping being a problem to be solved by the present invention. That is, when the boss 7 is provided on the source lead 14 by a stamping processing, the concave portion 20 is formed on the rear side of the boss 7. If there is no support pillar 16 to the concave portion 20, there is an issue such that the boss 7 is vibrated upon joining the bonding wire 4 to the source lead 14 by, for example, ultrasonic waves because of no support for the concave portion 20, and the ultrasonic energy is damped to lower the joint strength between the bonding wire 4 and the source lead 14. Accordingly, by forming the support pillar 16 to the concave portion 20 on the rear side of the boss 7, damping of the ultrasonic energy is prevented, so that the bonding wire 4 and the source lead 14 can be strongly joined.

In this manner, the joint strength between the bonding wire 4 and the source lead 14 is significantly improved, and disconnection and/or delamination of the bonding wire 4 are prevented before they occur, the disconnection and/or delamination being caused by the adhesive interface delamination resulting from a difference in thermal expansion coefficient between the resin 6 and the source lead 14 due to thermal load in a solder reflow process upon mounting the semiconductor device 9 on the substrate. Therefore, it is possible to provide a highly-reliable semiconductor device 9 without lowering the joint strength between the bonding wire 4 and the source lead 14. Also, since the boss 7 and the support pillar 16 according to the present embodiment can be easily formed by a pressing machine, the semiconductor device can be formed at a low cost for raw materials and processing.

Also, a plurality of sets of the boss 7 and the support pillar 16 may be provided in accordance with the number of lines of the bonding wires 4 joined to the source lead 14, and the plurality of sets may be individually provided. Further, a plurality of the bonding wires 4 may be joined to one set of the boss 7 and the support pillar 16.

Still further, the boss 7 and the support pillar 16 may be also formed in the gate lead 15, and also in this case, a joint strength between the bonding wire 3 and the gate lead 15 can be improved.

### Second Embodiment

A second embodiment is used for manufacture of a power MOSFET package, and will be described with reference to FIGS. 7 to 10.

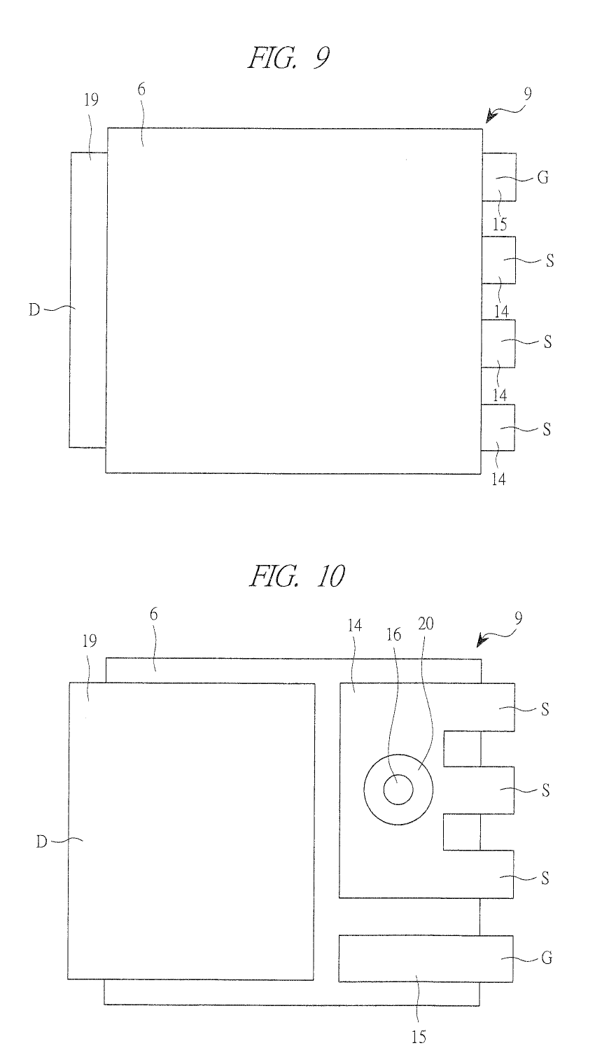

FIG. 7 is a cross-sectional view taken along the line B-B in FIG. 8, and illustrates an internal structure of a semiconductor device 9 according to the present embodiment. FIG. 8 is a plan view illustrating the internal structure of the semiconductor device 9 of FIG. 7, and an outline of a resin 6 is illustrated by a two-dot chain line. Also, FIGS. 9 and 10 illustrate appearance configurations of the semiconductor device 9 according to the present embodiment. FIG. 9 is a top plan view of the semiconductor device 9, and FIG. 10 is a bottom plan view of the same.

As illustrated in FIG. 7, the semiconductor device 9 according to the present embodiment has a bump 17 in a periphery of the bonding portion of the boss 7 in the semiconductor device 9 according to the first embodiment so as to continuously surround the bonding portion.

In the semiconductor device 9 according to the present embodiment, the bump 17 is continuously formed in the periphery of the boss 7 being the joint portion of the source lead 14 and the bonding wire 4. The boss 7 and the bump 17 are formed by, for example, a stamping processing, and for example, formed by a half stamping processing from the rear surface side of the source lead 14 with using a pressing machine.

The bump 17 prevents adhesive interface delamination between the resin 6 and the source lead 14, the adhesive interface delamination being a problem to be solved by the present invention. That is, by the anchor effect caused by continuously providing the bump 17 so as to surround the periphery of the bonding wire 4 joined to the boss 7 on the source lead 14, the adhesion between the resin 6 and the source lead 14 is further improved, so that the adhesive interface delamination between the resin 6 and the source lead 14 can be prevented. More particularly, since the bump 17 is continuously formed so as to surround the periphery of the bonding portion being the joint portion of the source lead 14 and the bonding wire 4, the bump 17 can protect the bonding portion from mechanical stress applied from every direction. That is, disconnection and/or delamination of the bonding wire 4 can be prevented before they occur, the disconnection and/or delamination being caused by the adhesive interface delamination resulting from a difference in thermal expansion coefficient between the resin 6 and the source lead 14 due to thermal load in a solder reflow process upon mounting the semiconductor device 9 on the substrate.

Further, similarly to the first embodiment, since the support pillar 16 is formed to the concave portion 20 on the rear side of the boss 7, damping of the ultrasonic energy upon joining the bonding wire 4 to the source lead 14 can be prevented. Still further, since the boss 7, the support pillar 16, and the bump 17 according to the present embodiment can be easily formed by a pressing machine, the semiconductor device can be formed at a low cost for raw materials and processing.

In this manner, the joint reliability between the bonding wire 4 and the source lead 14 is significantly improved, so that a highly-reliable semiconductor device 9 can be provided.

### Third Embodiment

A third embodiment is used for manufacture of a power-MOSFET package, and will be described with reference to FIGS. 11 to 14.

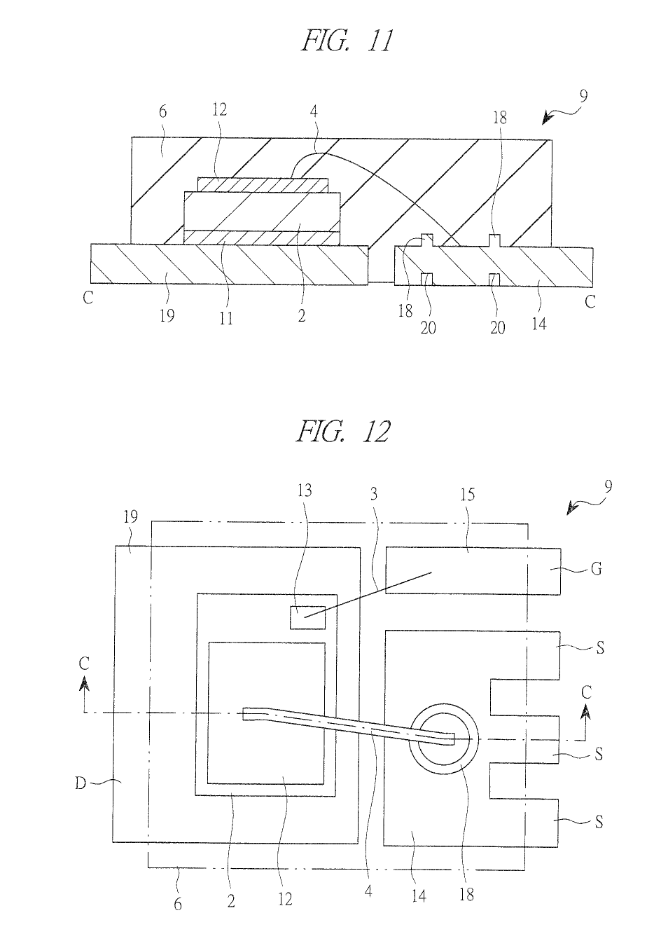

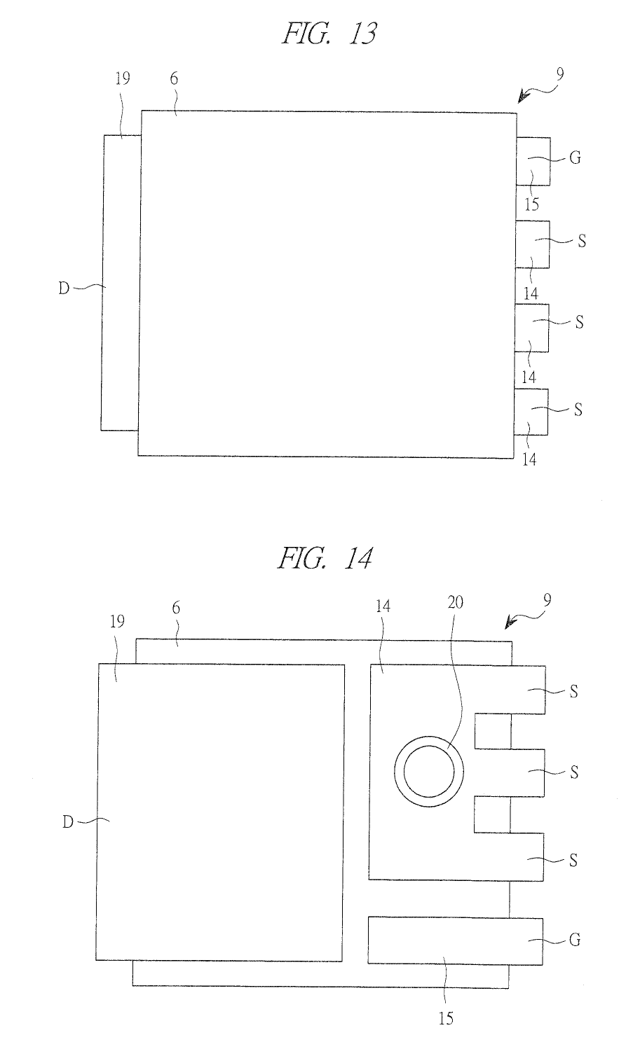

FIG. 11 is a cross-sectional view taken along the line C-C in FIG. 12, and illustrates an internal structure of a semiconductor device 9 according to the present embodiment. FIG. 12 is a plan view illustrating the internal structure of the semiconductor device 9 of FIG. 11, and an outline of a resin 6 is illustrated by a two-dot chain line. Also, FIGS. 13 and 14 illustrate appearance configurations of the semiconductor device 9 according to the present embodiment. FIG. 13 is a top plan view of the semiconductor device 9, and FIG. 14 is a bottom plan view of the same.

The semiconductor device 9 according to the present embodiment has a peripheral boss 18 on a periphery of the bonding portion so as to continuously surround the bonding portion instead of the boss 7 and the support pillar 16 in the semiconductor device 9 according to the first embodiment.

In the semiconductor device 9 according to the present embodiment, the peripheral boss 18 is continuously formed on a periphery of a joint portion of the source lead 14 and the bonding wire 4. The peripheral boss 18 is formed by, for example, a stamping processing, and for example, formed by a half stamping processing from the rear surface side of the source lead 14 with using a pressing machine.

The peripheral boss 18 prevents adhesive interface delamination between the resin 6 and the source lead 14, the adhesive interface delamination being a problem to be solved by the present invention. That is, by the anchor effect caused by continuously providing the peripheral boss 18 so as to surround the periphery of the bonding wire 4 joined onto the source lead 14, adhesion between the resin 6 and the source lead 14 is significantly improved, so that the adhesive interface delamination between the resin 6 and the source lead 14 can be prevented. More particularly, since the peripheral boss 18 is continuously formed so as to surround the periphery of the bonding portion being the joint portion of the source lead 14 and the bonding wire 4, the peripheral boss 18 can protect the bonding portion from mechanical stress applied from every direction. That is, disconnection and/or delamination of the bonding wire 4 can be prevented before they occur, the disconnection and/or delamination being caused by the adhesive interface delamination resulting from a difference in thermal expansion coefficient between the resin 6 and the source lead 14 due to thermal load in a solder reflow process upon mounting the semiconductor device 9 on the substrate. Also, since the peripheral boss 18 according to the present embodiment can be easily formed by a pressing machine, the semiconductor device can be formed at a low cost for raw materials and processing.

In this manner, joint reliability between the bonding wire 4 and the source lead 14 is significantly improved, so that a highly-reliable semiconductor device 9 can be provided.

### Fourth Embodiment

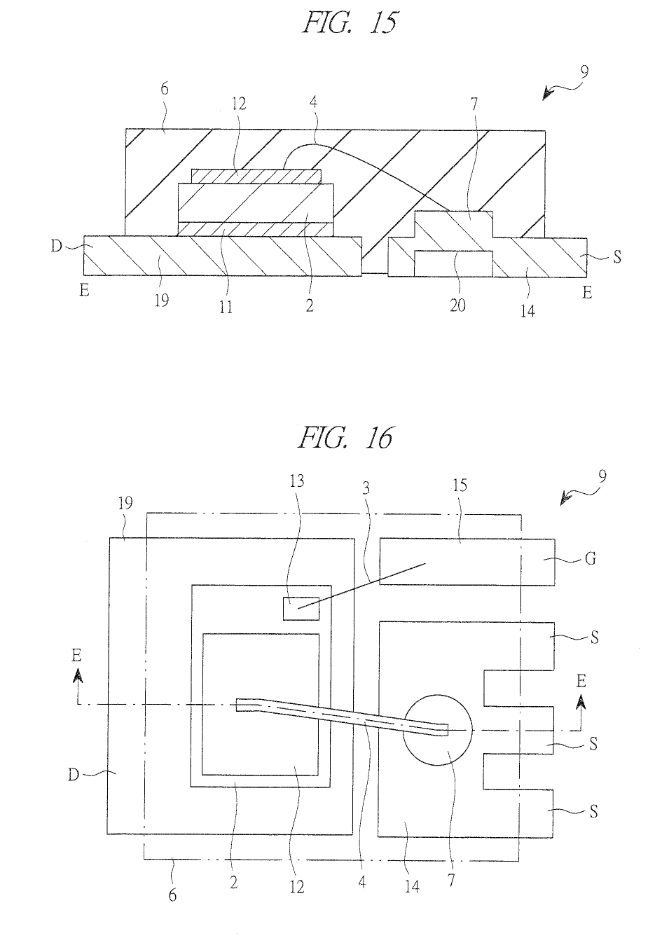

A fourth embodiment is used for manufacture of a power MOSFET package, and will be described with reference to FIGS. 15 to 19.

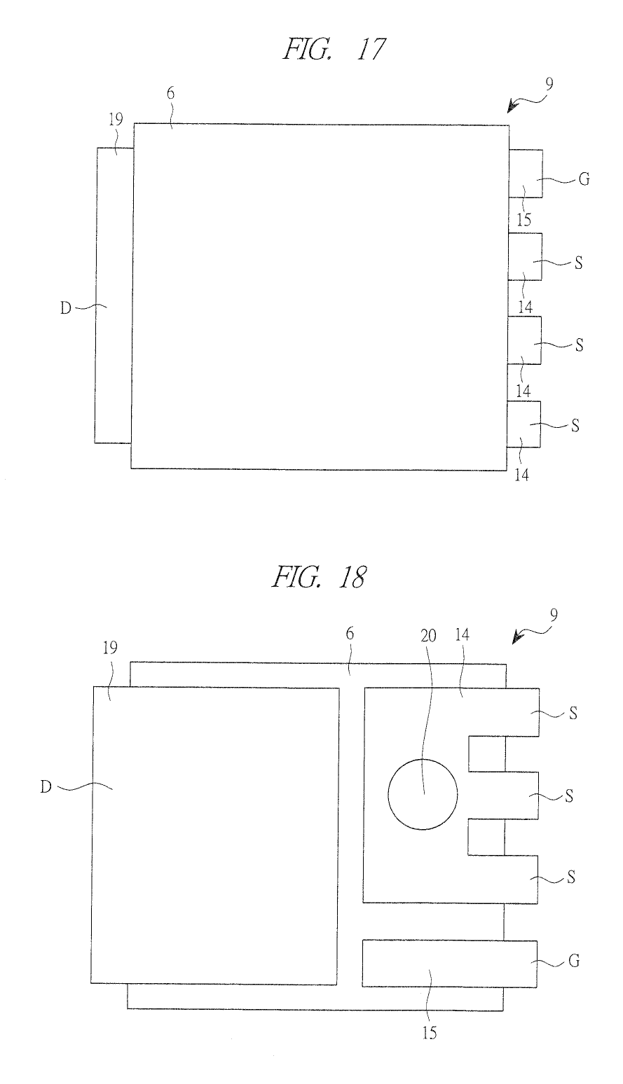

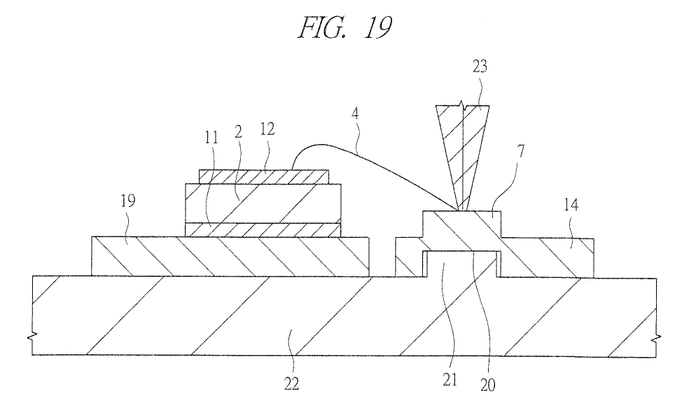

FIG. 15 is a cross-sectional view taken along the line E-E in FIG. 16, and illustrates an internal structure of a semiconductor device 9 according to the present embodiment. FIG. 16 is a plan view illustrating the internal structure of the semiconductor device 9 of FIG. 15, and an outline of a resin 6 is illustrated by a two-dot chain line. Also, FIGS. 17 and 18 illustrate appearance configurations of the semiconductor device 9 according to the present embodiment. FIG. 17 is a top plan view of the semiconductor device 9, and FIG. 18 is a bottom plan view of the same. FIG. 19 is a cross-sectional view illustrating the semiconductor device 9 according to the present embodiment in a manufacturing step.

The semiconductor device 9 according to the present embodiment has only a concave portion 20 in the semiconductor device 9 according to the first embodiment without providing the support pillar 16 on the rear surface of the boss 7.

In the semiconductor device 9 according to the present embodiment, the boss 7 is formed on the joint portion of the source lead 14 and the bonding wire 4. The boss 7 and the concave portion 20 on the rear surface of the source lead 14 are formed by, for example, a stamping processing, and for example, formed by a half stamping processing from the rear surface side of the source lead 14 with using a pressing machine.

By the anchor effect caused by providing the boss 7, adhesion between the resin 6 and the source lead 14 is improved, so that it is possible to suppress the delamination between the resin 6 and the source lead 14 due to thermal load in a solder reflow process upon mounting the semiconductor device 9 on the substrate.

At this time, the support pillar 16 according to the first embodiment is not formed in the concave portion 20 on the rear side of the boss 7. In the present embodiment, in order to prevent ultrasonic damping upon joining the source lead 14 and the bonding wire 4 which is a problem to be solved by the present invention, a base 22 previously having a boss 21 reaching a bottom surface of the concave portion 20 is used as a base for mounting the semiconductor device 9 in a step of joining the bonding wire 4 to the source lead 14 before a step of resin-molding the semiconductor device 9 by the resin 6 as illustrated in FIG. 19.

In this manner, for example, even if ultrasonic waves are applied from a tip of a capillary 23 to the bonding wire 4 upon jointing the bonding wire 4 to the source lead 14, the boss 21 to be a support of the concave portion 20 exists below the concave portion 20, and therefore, it is possible to prevent lowering of the joint strength between the bonding wire 4 and the source lead 14 caused by damping of the ultrasonic energy due to vibration of the boss 7.

That is, by using the base 22 having the boss 21 instead of the support pillar 16 according to the first embodiment, the boss 21 supports the boss 7 to suppress the damping of the ultrasonic energy, so that the bonding wire 4 and the source lead 14 can be strongly jointed. Also, since the boss 7 and the concave portion 20 according to the present embodiment can be easily formed by a pressing machine, the semiconductor device can be formed at a low cost for raw materials and processing.

In this manner, the joint reliability between the bonding wire 4 and the source lead 14 is significantly improved, so that a highly-reliable semiconductor device 9 can be provided.

Note that the wire bonding in FIG. 19 has been described with taking a joint by ball bonding for instance. However, the bonding wire 4 may be joined to the source lead 14 with applying ultrasonic waves by wedge bonding using wedge-bonding tools without using the capillary 23.

In the foregoing, the invention made by the present inventors has been concretely described based on the embodiments. However, it is needless to say that the present invention is not limited to the foregoing embodiments and various modifications and alterations can be made within the scope of the present invention.

The present invention can be used for manufacture of a semiconductor device in which an element such as a power MOSFET, an IGBT, or a bipolar power transistor electrically connected to a leadframe by wire bonding is resin-molded.

What is claimed is:

1. A semiconductor device comprising:
a leadframe having a first lead arranged on a die pad portion and in a vicinity of the die pad portion;
a semiconductor chip mounted on the die pad portion;
a bonding wire electrically connecting the first lead and an electrode formed on a surface of the semiconductor chip; and
a resin molding the semiconductor chip, the leadframe, the first lead, and the bonding wire, wherein
a boss to be a bonding portion of the bonding wire is provided on a top surface of the first lead at a joint surface between the first lead and the bonding wire, and a concave portion is formed on a part of a rear side of the boss.

2. The semiconductor device according to claim 1, wherein
the boss and the concave portion are formed by a stamping processing.

3. The semiconductor device according to claim 1, wherein
a support pillar formed of a part of the first lead is formed by a stamping processing, the support pillar being positioned right below the bonding portion inside the concave portion of the first lead and reaching the same height as that from a rear surface of the boss to a rear surface of the first lead.

4. The semiconductor device according to claim 1, wherein
a bump is continuously or discontinuously formed on a top surface of the boss so as to surround the bonding portion by a stamping processing.

5. The semiconductor device according to claim 1, wherein
the bonding wire is made of Al (aluminum).

6. The semiconductor device according to claim 1, wherein
the semiconductor chip is joined to the die pad portion via solder.

7. The semiconductor device according to claim 1, wherein
a power MOSFET is formed in the semiconductor chip, and the die pad portion forms a source electrode of the power MOSFET.

8. The semiconductor device according to claim 1, wherein
a rear side of the leadframe having the die pad portion is partially exposed, and the die pad portion and the leadframe also function as a heatsink.

9. A semiconductor device comprising:
a leadframe having a first lead arranged on a die pad portion and in a vicinity of the die pad portion;
a semiconductor chip mounted on the die pad portion;
a bonding wire electrically connecting the first lead and an electrode formed on a surface of the semiconductor chip; and
a resin molding the semiconductor chip, the leadframe, the first lead, and the bonding wire, wherein
a boss is continuously or discontinuously provided on a top surface of the leadframe at a joint surface between the first lead and the bonding wire so as to surround a bonding portion of the bonding wire, and a concave portion is formed on a part of a rear side of the bump.

10. The semiconductor device according to claim 9, wherein
the boss and the concave portion are formed by stamping processing.

11. The semiconductor device according to claim 9, wherein
the bonding wire is made of Al (aluminum).

12. The semiconductor device according to claim 9, wherein
the semiconductor chip is joined to the die pad portion via solder.

13. The semiconductor device according to claim 9, wherein
a power MOSFET is formed in the semiconductor chip, and the die pad portion forms a source electrode of the power MOSFET.

14. The semiconductor device according to claim 9, wherein
a rear side of the leadframe having the die pad portion is partially exposed, and the leadframe functions as a heatsink.
